(19) United States
(12) Patent Application Publication
(10) Pub. No.: US 2024/0230772 A1
(43) Pub. Date: Jul. 11, 2024

(54) METHOD FOR PROVIDING A STATE OF CHARGE OF A BATTERY CELL AND DEVICE FOR PROVIDING A STATE OF CHARGE OF A BATTERY CELL

(71) Applicant: VOLKSWAGEN AKTIENGESELLSCHAFT, Wolfsburg (DE)

(72) Inventor: Yi WANG, Wolfsburg (DE)

(21) Appl. No.: 18/536,380

(22) Filed: Dec. 12, 2023

(30) Foreign Application Priority Data
Jan. 5, 2023 (DE) 10 2023 200 072.5

(51) Int. Cl. G01R 31/3842; G01R 31/367; G01R 31/3828

(52) U.S. Cl. CPC G01R 31/3842; G01R 31/367; G01R 31/3828

(57) ABSTRACT

A method for providing a state of charge of a battery cell, measuring a voltage and a current across the battery cell that are the basis for estimating parameters of a battery cell model, using the estimated parameters and the battery cell model as a basis for estimating an open-circuit voltage of the battery cell which is used as a basis for determining a first state of charge of the battery cell by using a predefined lookup table and/or a predefined characteristic curve, determining a second state of charge by charge integration over time, the determined first state of charge is checked based on at least one checking criterion, and the determined first state of charge is the basis for providing the state of charge of the battery cell, and the determined second state of charge is the basis for providing the state of charge.

### PRIORITY CLAIM

This patent application claims priority to German Patent Application No. 10 2023 200 072.5, filed 5 Jan. 2023, the disclosure of which is incorporated herein by reference in its entirety.

### SUMMARY

Illustrative embodiments relate to a method for providing a state of charge of a battery cell and to an apparatus for providing a state of charge of a battery cell.

### BRIEF DESCRIPTION OF THE DRAWINGS

Disclosed embodiments will be explained in more detail below with reference to the figures, in which:

FIG. 1 shows a schematic illustration of an exemplary embodiment of the disclosed apparatus for providing a state of charge of a battery cell; and

FIG. 2 shows a schematic flowchart for demonstrating an exemplary embodiment of the disclosed method for providing a state of charge of a battery cell.

### DETAILED DESCRIPTION

Reliable knowledge of a state of charge (SOC) of a battery cell is important for many applications, in particular, in electric and hybrid transportation vehicles. It is known to determine a state of charge by charge integration during which the current of the battery cell is integrated in a direction-dependent manner over time.

CN 113030752 A discloses an online parameter-identification and SOC-estimation method based on a forgetting factor. The method comprises the following operations: creating a second-order lithium-battery equivalent-circuit model; determining a functional relationship between each parameter of the circuit and the SOC and establishing a state-space equation of the lithium battery; initializing an SOC state variable and a parameter state variable and estimating the SOC of the lithium battery by using an extended Kalman filter algorithm with a microscopic time scale; when the SOC estimation of the lithium battery reaches a preset time, switching over to a macroscopic time scale, identifying equivalent-circuit parameters by using a recursive least-squares method with a variable forgetting factor and finally updating the equivalent-circuit parameters and the state-space equation of the lithium battery to carry out a next round of calculations. According to the method, online parameter identification is carried out on the lithium-battery model by the recursive least-squares method with a variable forgetting factor, and the SOC of the lithium battery is estimated in combination with the extended Kalman filter algorithm.

The disclosed embodiments provide a method for providing a state of charge of a battery cell and an apparatus for providing a state of charge of a battery cell.

This is achieved by a method and an apparatus.

In particular, provision is made for a method for providing a state of charge of a battery cell, a voltage and a current across the battery cell being measured, the measured voltage and the measured current being used as a basis for estimating parameters of a battery cell model, the estimated parameters and the battery cell model being used as a basis for estimating an open-circuit voltage of the battery cell, the estimated open-circuit voltage being used as a basis for determining a first state of charge of the battery cell by using a predefined lookup table and/or a predefined characteristic curve, a second state of charge of the battery cell being determined by way of charge integration over time, the determined first state of charge being checked on the basis of at least one checking criterion, and the determined first state of charge being used as a basis for providing the state of charge of the battery cell if the at least one checking criterion is met, and the determined second state of charge being used as a basis for providing the state of charge of the battery cell if not.

Furthermore, provided is an apparatus for providing a state of charge of a battery cell, comprising an input interface configured for receiving a voltage measured across the battery cell and for receiving a current measured across the battery cell, and an evaluation device, the evaluation device being configured to receive the measured voltage and the measured current, to estimate parameters of a battery cell model on the basis of the measured voltage and the measured current, to estimate an open-circuit voltage of the battery cell on the basis of the estimated parameters and the battery cell model, to determine a first state of charge of the battery cell on the basis of the estimated open-circuit voltage by using a predefined lookup table and/or a predefined characteristic curve, to determine a second state of charge of the battery cell by way of charge integration over time, and to check the determined first state of charge on the basis of at least one checking criterion, the determined first state of charge being used as a basis for providing the state of charge of the battery cell if the at least one checking criterion is met, and the determined second state of charge being used as a basis for providing the state of charge of the battery cell if not.

The method and the apparatus allow an improved provision of a state of charge of the battery cell. The method provides a state-of-charge estimator by online parametrization of a battery cell model. In particular, a state of charge estimated on the basis of a battery cell model is checked. If the at least one checking criterion is met, the (first) state of charge determined on the basis of the battery cell model, which was parameterized on the basis of a determined present state of the battery cell, is provided. Conversely, if the at least one checking criterion is not met, the state of charge is thus provided on the basis of the (second) state of charge determined by way of charge integration over time (Coulomb integral), in particular, as a fallback level. As a result, accuracy of the provided state of charge can be increased and a value for the state of charge can still be provided at any time, that is to say even if the (first) state of charge determined in a model-based manner is rejected as invalid after the checking procedure.

The battery cell is a lithium-ion battery cell.

A state of charge (SOC) is a state-of-charge value. This value is expressed as a charge quantity, an energy quantity or a relative value with respect to a maximum battery cell capacity.

The battery cell model used is an equivalent circuit of the battery cell. In particular, a second-order equivalent circuit, that is to say with one series resistor and two RC elements, is used here.

The predefined lookup table contains an assignment of values of the state of charge to open-circuit voltages respectively corresponding thereto. A predefined characteristic curve represents this assignment via a function (SOCi=f(OCVi)). The assignment can, for example, be determined empirically on the basis of measurements on a laboratory test bench for a multiplicity of identical battery cells. The lookup table and/or characteristic curve determined in such a way are/is then predefined for the method and the apparatus. Provision can be made for the lookup table and/or the characteristic curve to represent a temperature dependency of the assignment. In this case, provision is made for a temperature of the battery cell to be measured or received and taken into consideration, for example, by selecting the lookup table and/or the characteristic curve for the present temperature of the battery cell.

The method operations are carried out continuously for individual time operations. In other words: A state of charge for present measured voltage and current values is determined and provided continuously. The parameters are estimated, in particular, online, that is to say during ongoing operation of the battery cell.

The method and the apparatus are used for providing a state of charge of a lithium-ion battery cell. In principle, the method can also be used for a plurality of battery cells. The method and the apparatus can be used, for example, in a vehicle, in particular, in a transportation vehicle.

Parts of the apparatus, in particular, the evaluation device, can, individually or together, be designed as a combination of hardware and software, for example, as program code, which is executed on a microcontroller or microprocessor. However, provision can also be made for parts, individually or together, to be designed as an application-specific integrated circuit (ASIC) and/or a field-programmable gate array (FPGA).

Provision can be made for the apparatus to comprise at least one voltage sensor for measuring a voltage of the battery cell and at least one current sensor for measuring a current of the battery cell.

Furthermore, also provided is a battery system comprising at least one apparatus according to one of the described embodiments.

In addition, provided is a transportation vehicle comprising at least one apparatus and/or at least one battery system according to one of the described embodiments.

In at least one exemplary embodiment, provision is made for the at least one checking criterion to involve that a change in the determined first state of charge is below a predefined relative value and/or absolute value over a predefined period. It is thus possible to ensure that the determined first state of charge can only change at a predefined rate of change. In particular, it is thus possible to catch fluctuations which arise due to measurement errors while measuring the voltage and the current.

In at least one exemplary embodiment, provision is made for the at least one checking criterion to involve that a difference between a change in the determined first state of charge and a change in the determined second state of charge is below a predefined absolute value. It is thus likewise possible to ensure that the determined first state of charge can only change at a predefined rate of change. In particular, it is thus possible to check the plausibility of the determined first state of charge on the basis of the determined second state of charge. If values for the changes in the first and the second state of charge differ too greatly from one another, the determined first state of charge is thus rejected.

In at least one exemplary embodiment, provision is made for the at least one checking criterion to involve that a difference between a measured voltage of the battery cell and the estimated open-circuit voltage is below a predefined absolute value. It is thus possible to check the plausibility of the underlying battery cell model, which subsequently increases the reliability of the provided state of charge.

In at least one exemplary embodiment, provision is made for the parameters of the battery cell model to be estimated using a variable-forgetting-factor recursive least-squares method. Here, a second-order equivalent circuit is used as the battery cell model. This equivalent circuit comprises a series resistor which is connected in series with two RC elements. The procedure is explained below by way of example.

The recursive least-squares (RLS) method is a method for online parameter identification. The RLS method was developed from the least-squares (LS) method. The principle of the RLS method with a forgetting factor is as follows.

$$y ( k ) = {φ}^{T} ( k ) θ + e ( k ) \qquad ( 1 )$$

$$e ( k ) = {U}_{L} ( k ) - {φ}^{T} ( k ) \hat{θ} ( k - 1 ) \qquad ( 2 )$$

$$K ( k ) = \frac{P ( k - 1 ) φ ( k )}{λ + {φ}^{T} ( k ) P ( k - 1 ) φ ( k )} \qquad ( 3 )$$

$$\hat{θ} ( k ) = \hat{θ} ( k - 1 ) + K ( k ) e ( k ) \qquad ( 4 )$$

$$P ( k ) = \frac{1}{λ} [ I - K ( k ) {φ}^{T} ( k ) ] P ( k - 1 ) \qquad ( 5 )$$

y(k) is the output of the system, φ^{T}(k) is the input of the system, \hat{θ} is the model parameter vector that is to be identified, K(k) is the amplification vector of the method, P(k) is the covariance matrix, e(k) is the estimation error and λ is the forgetting factor.

The RLS method with a variable forgetting factor is an improved method which adaptively finds the optimal value of the forgetting factor on the basis of the RLS method and accordingly the size of the estimation error e(k) in the parameter identification process. Using data windowing theory, the size of the variable forgetting factor is determined by the mean square value of the estimation error of a limited number of data points over a particular period of time, as a result of which the stability of the method is improved. The specific procedure is illustrated in the formula:

$$L ( k ) = - ρ \frac{{\sum }_{i = k - M + 1}^{k} {e}_{i} {e}_{i}^{T}}{M} \qquad ( 6 )$$

$$λ ( k ) = {λ}_{min} + ( {λ}_{max} - {λ}_{min} ) \cdot {2}^{L ( k )} \qquad ( 7 )$$

λ(k) is the variable forgetting factor, λₘₐₓ is the maximum forgetting factor, λₘᵢₙ is the minimum forgetting factor, eᵢ is the estimation error, M is the window size, ρ is a sensitivity factor.

The second-order equivalent circuit for a (lithium-ion) battery cell consists of an ideal voltage source U_{oc}, an ohmic resistor R0 and two RC parallel circuits. The current is positive in the charging direction. According to Kirchhoff's voltage law and Kirchhoff's current law, the relationships of the electrical characteristic equation are expressed in the equations:

$${U}_{L} = {U}_{oc} [ SOC ( t ) ] - {U}_{1} - {U}_{2} - I ( t ) \cdot {R}_{0} \qquad ( 8 )$$

$${C}_{1} \cdot \frac{{dU}_{1}}{dt} = I ( t ) - \frac{{U}_{1}}{{R}_{1}} \qquad ( 9 )$$

$${C}_{2} \cdot \frac{{dU}_{2}}{dt} = I ( t ) - \frac{{U}_{2}}{{R}_{2}} \qquad ( 10 )$$

U_{oc} is the open-circuit voltage (referred to as OCV or OCVi later on in the figures) of the (lithium-ion) battery cell, R₀ is the internal resistance of the battery cell, U_{L} is the battery cell terminal voltage (which corresponds to the measured voltage) and I the current (which corresponds to the measured current). The polarization resistance (R1, R2) and the polarization capacitance (C1, C2) are used to simulate the electrochemical polarization and concentration polarization.

The mathematical expressions of the above-mentioned models for high-performance battery cells are all continuous equations. In practical applications in which a battery management system (BMS) identifies the parameters by acquiring the data points individually, and the RLS method is a recursive method, it is necessary to convert the above-mentioned mathematical expressions into differential equations. Firstly, the Laplace transform of the frequency domain expression of the second-order RC equivalent circuit ascertains:

$$E ( s ) = {U}_{L} ( s ) - {U}_{oc} ( s ) = - I ( s ) ( {R}_{0} + \frac{{R}_{1}}{{R}_{1} {C}_{1} s + 1} + \frac{{R}_{2}}{{R}_{2} {C}_{2} s + 1} ) \qquad ( 11 )$$

Equation (11) is rewritten as:

$$G ( s ) = \frac{E ( s )}{I ( s )} = - ( {R}_{0} + \frac{{R}_{1}}{{R}_{1} {C}_{1} s + 1} + \frac{{R}_{2}}{{R}_{2} {C}_{2} s + 1} ) = - \frac{{R}_{0} {s}^{2} + \frac{\begin{matrix}{R}_{0} {R}_{1} {C}_{1} + {R}_{0} {R}_{2} {C}_{2} + \\ {R}_{2} {R}_{1} {C}_{1} + {R}_{1} {R}_{2} {C}_{2}\end{matrix}}{{R}_{1} {C}_{1} {R}_{2} {C}_{2}} s + \frac{{R}_{0} + {R}_{1} + {R}_{2}}{{R}_{1} {C}_{1} {R}_{2} {C}_{2}}}{{s}^{2} + \frac{{R}_{1} {C}_{1} + {R}_{2} {C}_{2}}{{R}_{1} {C}_{1} {R}_{2} {C}_{2}} s + \frac{1}{{R}_{1} {C}_{1} {R}_{2} {C}_{2}}} \qquad ( 12 )$$

The bilinear transform of the formula converts the transfer function of the system into the z-domain, and after simplification the following expression can be obtained:

$$s = \frac{2}{T} \frac{1 - {z}^{- 1}}{1 + {z}^{- 1}} \qquad ( 13 )$$

$$G ( {z}^{- 1} ) = \frac{{k}_{3} + {k}_{4} {z}^{- 1} + {k}_{5} {z}^{- 2}}{1 - {k}_{1} {z}^{- 1} - {k}_{2} {z}^{- 2}} \qquad ( 14 )$$

$${k}_{1} = \frac{2 {T}^{2} - 8 {R}_{1} {C}_{1} {R}_{2} {C}_{2}}{- {T}^{2} - 2 T ( {R}_{1} {C}_{1} + {R}_{2} {C}_{2} ) - 4 {R}_{1} {C}_{1} {R}_{2} {C}_{2}} \qquad ( 15 )$$

$${k}_{2} = \frac{{T}^{2} - 2 T ( {R}_{1} {C}_{1} + {R}_{2} {C}_{2} ) + 4 {R}_{1} {C}_{1} {R}_{2} {C}_{2}}{- {T}^{2} - 2 T ( {R}_{1} {C}_{1} + {R}_{2} {C}_{2} ) - 4 {R}_{1} {C}_{1} {R}_{2} {C}_{2}} \qquad ( 16 )$$

$${k}_{3} = \frac{\begin{matrix}( {T}^{2} ( {R}_{0} + {R}_{1} + {R}_{2} ) + 2 T ( {R}_{0} {R}_{1} {C}_{1} + {R}_{0} {R}_{2} {C}_{2} + \\ {R}_{1} {R}_{2} {C}_{2} + {R}_{2} {R}_{1} {C}_{1} ) + 4 {R}_{0} {R}_{1} {C}_{1} {R}_{2} {C}_{2} )\end{matrix}}{( - {T}^{2} - 2 T ( {R}_{1} {C}_{1} + {R}_{2} {C}_{2} ) - 4 {R}_{1} {C}_{1} {R}_{2} {C}_{2} )} \qquad ( 17 )$$

$${k}_{4} = \frac{2 {T}^{2} ( {R}_{0} + {R}_{1} + {R}_{2} ) - 8 {R}_{0} {R}_{1} {C}_{1} {R}_{2} {C}_{2}}{- {T}^{2} - 2 T ( {R}_{1} {C}_{1} + {R}_{2} {C}_{2} ) - 4 {R}_{1} {C}_{1} {R}_{2} {C}_{2}} \qquad ( 18 )$$

$${k}_{5} = \frac{\begin{matrix}( {T}^{2} ( {R}_{0} + {R}_{1} + {R}_{2} ) - 2 T ( {R}_{0} {R}_{1} {C}_{1} + {R}_{0} {R}_{2} {C}_{2} + \\ {R}_{1} {R}_{2} {C}_{2} + {R}_{2} {R}_{1} {C}_{1} ) + 4 {R}_{0} {R}_{1} {C}_{1} {R}_{2} {C}_{2} )\end{matrix}}{( - {T}^{2} - 2 T ( {R}_{1} {C}_{1} + {R}_{2} {C}_{2} ) - 4 {R}_{1} {C}_{1} {R}_{2} {C}_{2} )} \qquad ( 19 )$$

The recursive equations (20) and (21) therefore result from equation (14):

$$E ( k ) = {k}_{1} E ( k - 1 ) + {k}_{2} E ( k - 2 ) + {k}_{3} I ( k ) + {k}_{4} I ( k - 1 ) + {k}_{5} I ( k - 2 ) \qquad ( 20 )$$

$${U}_{L} ( k ) = ( 1 - {k}_{1} - {k}_{2} ) {U}_{oc} ( k ) + {k}_{1} {U}_{L} ( k - 1 ) + {k}_{2} {U}_{L} ( k - 2 ) + {k}_{3} I ( k ) + {k}_{4} I ( k - 1 ) + {k}_{5} I ( k - 2 ) \qquad ( 21 )$$

According to the description of the system equation in the RLS method, y(k) is defined as the output of the system, φ^{T}(k) as the input of the system, θ as the model parameter vector that is to be identified. The system equation in matrix form:

$$y ( k ) = {φ}^{T} ( k ) θ \qquad ( 22 )$$

$$φ ( k ) = {[ 1 , {U}_{L} ( k - 1 ) , {U}_{L} ( k - 2 ) , I ( k ) , I ( k - 1 ) , I ( k - 2 ) ]}^{T} \qquad ( 23 )$$

$$θ = [ {k}_{6} , {k}_{1} , {k}_{2} , {k}_{3} , {k}_{4} , {k}_{5} ] \qquad ( 24 )$$

$${k}_{6} = - ( 4 {τ}_{1} {τ}_{2} + 2 {τ}_{1} T + 2 {τ}_{2} T + {T}^{2} ) \qquad ( 25 )$$

The parameters which are incorporated in the identification result of the RLS method are k₆, k₁, k₂, k₃, k₄, k₅, but the five parameters R0, R1, C1, R2 and C2 are actually required. Therefore, it can be solved inversely according to the formula by:

$${R}_{0} = \frac{- {k}_{3} + {k}_{4} - {k}_{5}}{1 + {k}_{1} - {k}_{2}} \qquad ( 26 )$$

$${R}_{1} {C}_{1} {R}_{2} {C}_{2} = \frac{{T}^{2} ( 1 + {k}_{1} - {k}_{2} )}{4 ( 1 - {k}_{1} - {k}_{2} )} \qquad ( 27 )$$

$${R}_{1} {C}_{1} + {R}_{2} {C}_{2} = \frac{T ( 1 + {k}_{2} )}{1 - {k}_{1} - {k}_{2}} \qquad ( 28 )$$

$${R}_{0} + {R}_{1} + {R}_{2} = \frac{- {k}_{3} - {k}_{4} - {k}_{5}}{1 - {k}_{1} - {k}_{2}} \qquad ( 29 )$$

$${R}_{0} {R}_{1} {C}_{2} + {R}_{0} {R}_{2} {C}_{2} + {R}_{2} {R}_{1} {C}_{1} + {R}_{1} {R}_{2} {C}_{2} = \frac{T ( {k}_{5} - {k}_{3} )}{1 - {k}_{1} - {k}_{2}} \qquad ( 30 )$$

With the intermediate parameters:

$$a = {T}^{2} * \frac{( 1 + {k}_{1} + {k}_{2} )}{[ 4 * ( 1 - {k}_{1} - {k}_{2} ) ]} \qquad ( 31 )$$

$$b = T * \frac{( 1 + {k}_{2} )}{( 1 - {k}_{1} - {k}_{2} )} \qquad ( 32 )$$

$$c = \frac{( - {k}_{3} + {k}_{4} + {k}_{5} )}{( 1 - {k}_{1} - {k}_{2} )} \qquad ( 33 )$$

$$d = T * \frac{( {k}_{5} - {k}_{3} )}{( 1 - {k}_{1} - {k}_{2} )} \qquad ( 34 )$$

The parameters of the battery cell model then result as follows:

$${τ}_{1} = min \{ [ b - {( {b}^{2} - 4 * a )}^{∧} ( 1 / 2 ) ] / 2 , [ b + {( {b}^{2} - 4 * a )}^{∧} ( 1 / 2 ) ] \}$$

$${τ}_{2} = max \{ [ b - {( {b}^{2} - 4 * a )}^{∧} ( 1 / 2 ) ] / 2 , [ b + {( {b}^{2} - 4 * a )}^{∧} ( 1 / 2 ) ] \}$$

$${R}_{1} = \frac{( {τ}_{1} * c + {R}_{0} * b - {R}_{0} * {τ}_{1} - d )}{( {τ}_{1} - {τ}_{2} )} \qquad ( 37 )$$

$${R}_{2} = c - {R}_{0} - {R}_{1} \qquad ( 38 )$$

$${C}_{1} = \frac{{τ}_{1}}{{R}_{1}} \qquad ( 39 )$$

$${C}_{2} = \frac{{τ}_{2}}{{R}_{2}} \qquad ( 40 )$$

$${U}_{oc} = \frac{{k}_{6}}{( 1 - {k}_{1} - {k}_{2} )} \qquad ( 41 )$$

In at least one exemplary embodiment, provision is made for estimated parameters and/or the estimated open-circuit voltage and/or the determined first state of charge not to be taken into consideration for a predefined duration if at least one selected checking criterion from among the at least one checking criterion is not met. As a result, erroneous and/or invalid values can be rejected. In particular, it is thus possible to wait for the predefined duration, that is to say until the values are valid again. For example, provision can be made to define the predefined duration as a predefined number of time operations, the values of which are not taken into consideration during the determination of the first state of charge.

In at least one exemplary embodiment, provision is made for the state of charge to be set to be equal to the determined first state of charge if a difference between the determined first state of charge and the determined second state of charge is less than a predefined relative value and/or absolute value. As a result, even when the determined first state of charge is valid, that is to say if the at least one checking criterion is met, it can be checked for plausibility on the basis of the determined second state of charge.

In at least one exemplary embodiment, provision is made for a weighted sum of the determined first state of charge and of the determined second state of charge to be used as a basis for determining the state of charge if the difference between the determined first state of charge and the determined second state of charge is greater than or equal to the predefined relative value and/or absolute value. As a result, a weighted average of the determined first state of charge and of the determined second state of charge can be used as a basis for providing the state of charge. A respective weighting factor can be predefined here, it being possible to determine the weighting factor on the basis of empirical test series, for example.

Further features for the configuration of the apparatus are evident from the description of configurations of the method. The benefits of the apparatus here are in each case the same as for the configurations of the method.

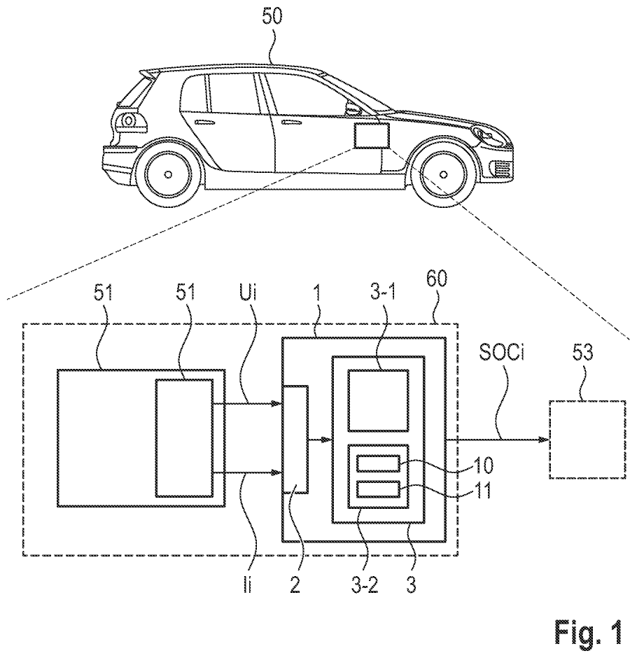

FIG. 1 shows a schematic illustration of an exemplary embodiment of the apparatus 1 for providing a state of charge SOCi of a battery cell 51, the index i here and below always standing for a time operation. The apparatus 1 is, for example, arranged in a vehicle 50, in particular, in a transportation vehicle.

The apparatus 1 comprises an input interface 2 and an evaluation device 3. The input interface 2 is configured for receiving a voltage Ui across the battery cell 51 and for receiving a current Ii across the battery cell 51 and transmits the measured voltage Ui and the measured current Ii to the evaluation device 3. The measured voltage Ui and the measured current Ii are transmitted to the input interface 2 by a battery management system 52, for example. The battery cell 51, the battery management system 52 and the apparatus I form a battery system 60.

The evaluation device 3 comprises a computing device 3-1 and a storage unit 3-2. The computing device 3-1, for example, a microprocessor, is configured to perform computing operations required for carrying out the method described in this disclosure.

The evaluation device 3 is configured to receive the measured voltage Ui and the measured current Ii. The evaluation device 3 uses the measured voltage Ui and the measured current Ii as a basis for estimating parameters of a battery cell model. The evaluation device 3 furthermore uses the estimated parameters and the battery cell model as a basis for estimating an open-circuit voltage of the battery cell 51. The evaluation device 3 uses the estimated open-circuit voltage as a basis for determining a first state of charge SOC1i of the battery cell 51 by using a predefined lookup table 10 and/or a predefined characteristic curve 11. The predefined lookup table 10 and/or the predefined characteristic curve 11 are stored in the storage unit 3-2 for this purpose and are retrieved therefrom. Provision can be made for a temperature of the battery cell 51 to be measured by a suitable sensor (not shown) and taken into consideration when selecting the lookup table 10 and/or the characteristic curve 11. Furthermore, the lookup table 10 and/or the characteristic curve 11 can also contain and/or represent a temperature dependency.

The evaluation device 3 furthermore determines a second state of charge SOC2i of the battery cell 51 by way of charge integration over time. This is done over the entire operating duration of the battery cell 51.

In addition, the evaluation device 3 checks the determined first state of charge SOC1i on the basis of at least one checking criterion and uses the determined first state of charge as a basis for providing the state of charge SOCi of the battery cell 51 if the at least one checking criterion is met. If not, the evaluation device 3 uses the determined second state of charge as a basis for providing the state of charge SOCi of the battery cell 51. The state of charge SOCi is, for example, supplied to a vehicle controller 53 and is used there, for example, to determine a remaining range of the transportation vehicle 50.

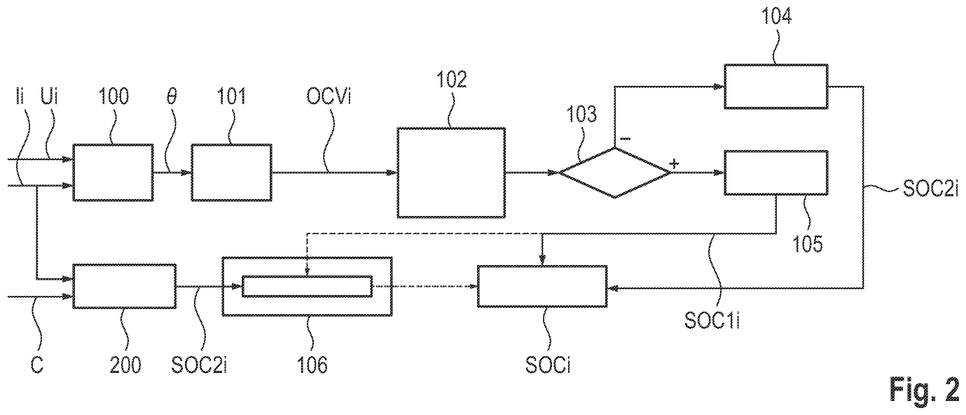

FIG. 2 shows a schematic flowchart for demonstrating an exemplary embodiment of the method for providing the state of charge SOCi of the battery cell 51. The method is carried out, for example, by the exemplary embodiment of the disclosed apparatus 1 shown in FIG. 1.

In an operation at 100, the measured voltage Ui and the measured current Ii are used as a basis for estimating parameters θ of the battery cell model (in particular, as a parameter vector). Here, provision is made for the parameters θ of the battery cell 51 to be estimated using a variable-forgetting-factor recursive least-squares method. In particular, a second-order equivalent circuit is used as the battery cell model here. The procedure here was already explained above in the general description. In an operation at 101, the estimated parameters θ and the battery cell model are used as a basis for estimating the open-circuit voltage OCVi.

In an operation at 102, the estimated open-circuit voltage OCVi is used as a basis for determining a first state of charge SOC1i of the battery cell 51 by using a predefined lookup table and/or a predefined characteristic curve.

In an operation at 200, simultaneously, the measured current Ii is used as a basis for determining a second state of charge SOC2i of the battery cell 51 by way of charge integration over time. Here, a capacity C of the battery cell 51 is taken into consideration.

In an operation at 103, the determined first state of charge SOC1i is checked on the basis of at least one checking criterion.

Here, provision can be made for the at least one checking criterion to involve that a change in the determined first state of charge SOC1i is below a predefined relative value and/or absolute value over a predefined period (i.e., over a predefined number of time operations).

Here, provision can furthermore be made for the at least one checking criterion to involve that a difference between a change in the determined first state of charge SOC1i and a change in the determined second state of charge SOC2i is below a predefined absolute value.

In addition, provision can be made for the at least one checking criterion to involve that a difference between a measured voltage Ui of the battery cell 51 and the estimated open-circuit voltage OCVi is below a predefined absolute value.

Provision can be made for all three mentioned checking criteria needing to be met.

If the at least one checking criterion is not met, the determined second state of charge SOC2i is thus used as a basis for providing the state of charge SOCi of the battery cell 51 in an operation at 104.

Conversely, if the at least one checking criterion is met, the determined first state of charge SOC1i is thus used as a basis for providing the state of charge SOCi of the battery cell 51 in an operation at 105.

Provision can be made in an operation at 106 for the state of charge SOCi to be set to be equal to the determined first state of charge SOC1i if a difference between the determined first state of charge SOC1i and the determined second state of charge SOC2i is less than a predefined relative value and/or absolute value. The predefined relative value can be a few percent, for example, 2%, 3% or 4%.

Provision can furthermore be made in operation at 106 for a weighted sum of the determined first state of charge SOC1i and of the determined second state of charge SOC2i to be used as a basis for determining the state of charge SOCi if the difference between the determined first state of charge SOC1i and the determined second state of charge SOC2i is greater than or equal to the predefined relative value and/or absolute value. The weighting factors can be predefined here.

Provision can be made for estimated parameters θ and/or the estimated open-circuit voltage OCVi and/or the determined first state of charge SOC1i not to be taken into consideration for a predefined duration if at least one selected checking criterion from among the at least one checking criterion is not met. For example, the values for a predefined number of time operations can remain unconsidered.

### LIST OF REFERENCE SIGNS

1 apparatus
2 input interface
3 evaluation device
3-1 computing device
3-2 storage unit
10 lookup table
11 characteristic curve
50 transportation vehicle
51 battery cell
52 battery management system
53 vehicle controller
60 battery system
C capacity
Ii current
SOCi state of charge
SOC1i first state of charge
SOC2i second state of charge
OCVi open-circuit voltage
Ui voltage
θ parameters (battery cell model)
100-107 operations of the method
200 operations of the method

1. An apparatus for providing a state of charge of a battery cell, the apparatus comprising:
an input interface configured to receive a voltage measured across the battery cell and receipt of a current measured across the battery cell; and
an evaluation device,
wherein the evaluation device:
receives the measured voltage and the measured current,
estimates parameters of a battery cell model based on the measured voltage and the measured current,
estimates an open-circuit voltage of the battery cell based on the estimated parameters and the battery cell model,
determines a first state of charge of the battery cell based on the estimated open-circuit voltage by using a predefined lookup table and/or a predefined characteristic curve,
determines a second state of charge of the battery cell by charge integration over time, and
checks the determined first state of charge based on at least one checking criterion, the determined first state of charge being used as a basis for providing the state of charge of the battery cell in response to the at least one checking criterion being met, and the determined second state of charge being used as a basis for providing the state of charge of the battery cell in response to the at least one checking criterion not being met.

2. A battery system comprising at least one apparatus of claim 1.

3. The apparatus of claim 1, wherein the at least one checking criterion includes a determining whether a change in the determined first state of charge is below a predefined relative value and/or absolute value over a predefined period.

4. The apparatus of claim 1, wherein the at least one checking criterion includes a determining whether a difference between a change in the determined first state of charge and a change in the determined second state of charge is below a predefined absolute value.

5. The apparatus of claim 1, wherein the at least one checking criterion includes a determining whether a difference between a measured voltage of the battery cell and the estimated open-circuit voltage is below a predefined absolute value.

6. The apparatus of claim 1, wherein the parameters of the battery cell model are estimated using a variable-forgetting-factor recursive least-squares method.

7. The apparatus of claim 1, wherein estimated parameters and/or the estimated open-circuit voltage and/or the determined first state of charge are not considered for a predefined duration in response to at least one selected checking criterion from among the at least one checking criterion not being met.

8. The apparatus of claim 1, wherein the state of charge is set to be equal to the determined first state of charge in response to a difference between the determined first state of charge and the determined second state of charge being less than a predefined relative value and/or absolute value.

9. The apparatus of claim 8, wherein a weighted sum of the determined first state of charge and of the determined second state of charge is used as a basis for determining the state of charge in response to the difference between the determined first state of charge and the determined second state of charge being greater than or equal to the predefined relative value and/or absolute value.

10. A method for providing a state of charge of a battery cell, the method comprising:
measuring a voltage and a current across the battery cell;
using the measured voltage and the measured current as a basis for estimating parameters of a battery cell model;
using the estimated parameters and the battery cell model as a basis for estimating an open-circuit voltage of the battery cell;
using the estimated open-circuit voltage as a basis for determining a first state of charge of the battery cell by using a predefined lookup table and/or a predefined characteristic curve;
determining a second state of charge of the battery cell by charge integration over time;
checking the determined first state of charge based on at least one checking criterion;
using the determined first state of charge as a basis for providing the state of charge of the battery cell in response to the at least one checking criterion being met; and
using the determined second state of charge as a basis for providing the state of charge of the battery cell in response to the at least one checking criterion not being met.

11. The method of claim 10, wherein the at least one checking criterion includes a determining whether a change in the determined first state of charge is below a predefined relative value and/or absolute value over a predefined period.

12. The method of claim 10, wherein the at least one checking criterion includes a determining whether a difference between a change in the determined first state of charge and a change in the determined second state of charge is below a predefined absolute value.

13. The method of claim 10, wherein the at least one checking criterion includes a determining whether a difference between a measured voltage of the battery cell and the estimated open-circuit voltage is below a predefined absolute value.

14. The method of claim 10, wherein the parameters of the battery cell model are estimated using a variable-forgetting-factor recursive least-squares method.

15. The method of claim 10, wherein estimated parameters and/or the estimated open-circuit voltage and/or the determined first state of charge are not considered for a predefined duration in response to at least one selected checking criterion from among the at least one checking criterion not being met.

16. The method of claim 10, wherein the state of charge is set to be equal to the determined first state of charge in response to a difference between the determined first state of charge and the determined second state of charge being less than a predefined relative value and/or absolute value.

17. The method of claim 16, wherein a weighted sum of the determined first state of charge and of the determined second state of charge is used as a basis for determining the state of charge in response to the difference between the determined first state of charge and the determined second state of charge being greater than or equal to the predefined relative value and/or absolute value.
